(19) United States
(12) Patent Application Publication
(10) Pub. No.: US 2009/0108390 A1
(43) Pub. Date: Apr. 30, 2009

(54) Image Sensor and Method for Manufacturing Thereof

(76) Inventor: Han Choon LEE, Seoul (KR)

Correspondence Address: THE LAW OFFICES OF ANDREW D. FORTNEY, PH.D., P.C., 401 W FALLBROOK AVE STE 204, FRESNO, CA, 93711-5835, US

(21) Appl. No.: 12/260,839

(22) Filed: Oct. 29, 2008

(30) Foreign Application Priority Data
Oct. 31, 2007 (KR) 10-2007-0110049

(51) Int. Cl. H01L 31/0216; H01L 31/18

(52) U.S. Cl. 257/446; 438/98; 257/E31.119

(57) ABSTRACT

An image sensor may include a semiconductor substrate including a device isolating film and a light receiving device; an insulating film on the semiconductor substrate; a barrier; a metal wire layer on the insulating film; a trench between adjacent metal wires having a protective film pattern on sidewalls thereof; and a photosensitive material in the trench. A method for manufacturing an image sensor may comprise forming an insulating film on a semiconductor substrate, the semiconductor substrate having a device isolating film, a barrier and a light receiving device; forming a metal wire layer on the insulating film; forming a trench between adjacent metal wires; forming a protective film pattern on sidewall surfaces of the trench; forming a photosensitive material over the metal wire layer and in the trench; and planarizing the semiconductor substrate to remove portions of the photosensitive material over the metal wire layer.

The present application claims priority under 35 U.S.C. 119 to Korean Patent Application No. 10-2007-0110049 (filed on Oct. 31, 2007), which is hereby incorporated by reference in its entirety.

### TECHNICAL FIELD

Embodiments of the present invention relate to an image sensor and a method for manufacturing thereof.

### BACKGROUND

### Description of the Related Art

An image sensor is a semiconductor device for converting optical images into electrical signals, and may be classified into a charge coupled device (CCD) image sensor and a complementary metal oxide silicon (CMOS) image sensor.

The CMOS image sensor includes a photodiode and MOS transistors within each unit pixel to sequentially detect electrical signals of each unit pixel to realize an image.

### SUMMARY

Embodiments of the present invention provide an image sensor comprising: a semiconductor substrate including a device isolating film and a light receiving device; an insulating film on the semiconductor substrate; a barrier; a metal wire layer on the insulating film; a trench between adjacent metal wires having a protective film pattern on sidewalls thereof; and a photosensitive material in the trench.

Embodiments of the present invention also provide a method for manufacturing an image sensor comprising the steps of: forming an insulating film on a semiconductor substrate, the semiconductor substrate having a device isolating film, a barrier and a light receiving device; forming a metal wire layer on the insulating film; forming a trench between adjacent metal wires in the metal wire layer; forming a protective film on surfaces of the trench; forming a first protective film pattern by removing the protective film from the bottom surface of the trench; forming a photosensitive material over the metal wire layer and in the trench; and planarizing the semiconductor substrate to remove portions of the photosensitive material over the metal wire layer.

### BRIEF DESCRIPTION OF THE DRAWINGS

FIGS. 1 to 9 are cross-sectional views showing a method for manufacturing an image sensor according to embodiments of the present invention.

FIG. 10 is a layout view of an exemplary unit pixel containing 4 transistors in accordance with an embodiment of the present invention.

### DETAILED DESCRIPTION OF THE EMBODIMENTS

Hereinafter, an image sensor and a method for manufacturing the same according to embodiments of the present invention will be described in detail with reference to the accompanying drawings.

In the description of various embodiments, it will be understood that when a layer (or film) is referred to as being ‘on’ another layer or substrate, it can be directly on another layer or substrate, or one or more intervening layers may also be present. Further, it will be understood that when a layer is referred to as being ‘under’ another layer, it can be directly under another layer, or one or more intervening layers may also be present.

The drawings show a structure of a CMOS image sensor (CIS), however, the present invention is not limited to a CMOS image sensor but is applicable to all image sensors including a CCD image sensor.

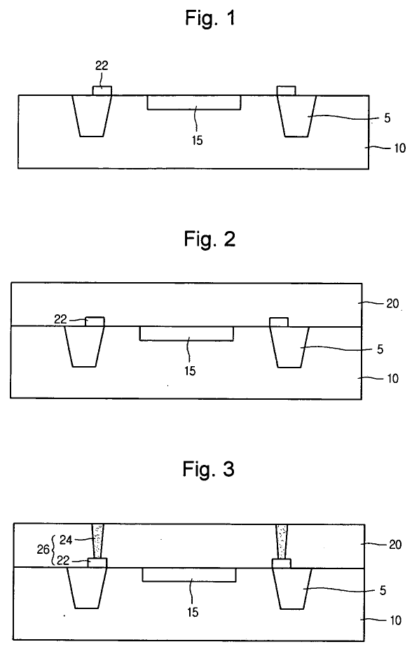

FIGS. 1 to 9 are cross-sectional views showing a method for manufacturing an image sensor according to various embodiments.

First, as shown in FIG. 1, a poly-silicon pattern 22 is formed on a semiconductor substrate 10 having a device isolating film 5 and one or more light receiving devices 15 therein.

In the semiconductor substrate 10, a low-concentration p type epitaxial layer (not shown) may be formed on a high-concentration p++ type silicon substrate. The presence of a low-concentration p type epitaxial layer may result in a depletion region of a photodiode of increased width and depth, making it possible to increase the ability of the photodiode to collect photocharges.

If the high-concentration p++ type substrate is provided on a lower portion of the p type epitaxial layer, the photocharges may be recombined before they are diffused to an adjacent unit pixel, making it possible to reduce change of transferring functions of the photocharges (e.g. reduce variations in photocharges transferred from the photodiode) by reducing random diffusion of the photocharges.

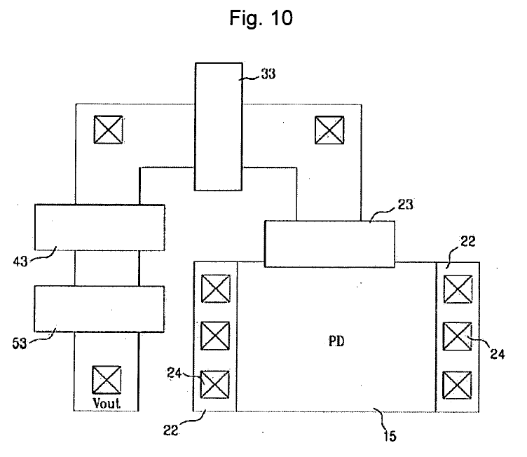

The device isolating film 5 may be formed by patterning and etching a trench in the semiconductor substrate 10 and then depositing an insulating material into the trench. The light receiving device 15 may comprise a photodiode, and a transistor comprising gate 23 transmits a signal from the light receiving device 15. The poly-silicon pattern 22 may be formed by depositing and then patterning a poly-silicon film. Other gates (e.g. transfer transistor gate 23; see FIG. 10) may be formed at the same time as the polysilicon pattern 22, and the source and drain terminals can be formed in the substrate thereafter.

As shown in FIG. 2, a pre-metal insulating film 20 is formed on the semiconductor substrate 10 including the poly-silicon pattern 22 (and transistor gates 23, 33, 43, and 53; see FIG. 10). The pre-metal insulating film 20 may comprise a lowermost, conformal etch stop layer (e.g., silicon nitride), a conformal buffer and/or gap-fill layer (e.g., silicon-rich oxide [SRO], TEOS [e.g., a silicon oxide formed by CVD from tetraethyl orthosilicate and oxygen], an undoped silicate glass [USG] or a combination thereof), a bulk dielectric layer (e.g., one or more silicon oxide layers doped with boron and/or phosphorous [BSG, PSG and/or BPSG]), and a capping layer (e.g., of TEOS, USG, a plasma silane [e.g., silicon dioxide formed by plasma-assisted CVD of silicon dioxide from silane and oxygen], or a combination thereof, such as a bilayer of plasma silane on USG or TEOS, or a bilayer of USG on TEOS).

As shown in FIG. 3, a tungsten plug 24 comprising tungsten (W) is formed in the pre-metal insulating film 20 to form a barrier 26 on the pre-metal insulating film 20. The tungsten plug 24 may be formed by patterning and etching a via on the pre-metal insulating film 20 and then filling the via with tungsten. A barrier metal layer and/or adhesive metal layer (not shown) may be further formed on the substrate 10 prior to deposition of the tungsten. For example, the adhesive metal layer may comprise aluminum, titanium or tantalum, and the barrier metal layer may comprise one or more of tungsten, titanium, tantalum, and nitrides and/or alloys thereof. The tungsten plug 24 may be formed in part on the poly-silicon pattern 22.

The barrier 26 comprising the poly-silicon pattern 22 and the tungsten plug 24 causes reflection of incident light in order to reduce or prevent incident light from being emitted externally, thereby increasing the amount of light incident upon light receiving device 15.

In a preferred embodiment, the barrier 26 comprises the poly-silicon pattern 22 and the tungsten plug 24. However, it is not limited thereto. The barrier 26 may comprise the tungsten plug 24 only.

FIG. 10 is a top down view of a structure similar to that of FIG. 3, showing the poly-silicon pattern 22 arranged along opposite sides of the photodiode 15, with tungsten plugs 24 arranged linearly along the poly-silicon pattern 22. The tungsten plugs 24 may be replaced by a single elongated tungsten structure in a trench that penetrates the entire thickness of dielectric layer 20, instead of multiple vias 24.

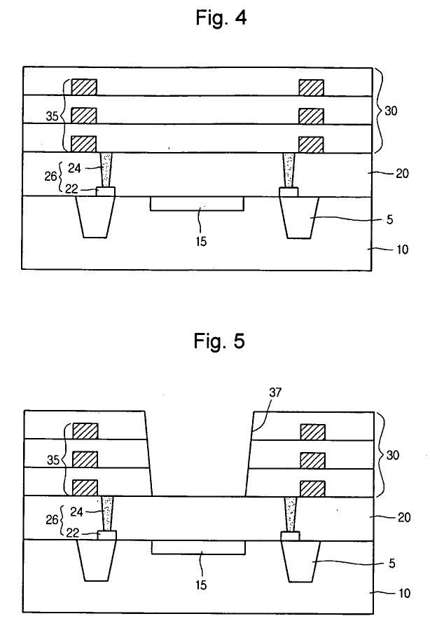

As shown in FIG. 4, a plurality of insulator layers 30 and a plurality of metal wires 35 are formed on the pre-metal insulating film 20 including the barrier 26. Metal wires 35 may each comprise aluminum or an aluminum alloy (e.g., Al with up to 4 wt. % Cu, up to 2 wt. % Ti, and/or up to 1 wt. % Si), on conventional adhesion and/or barrier layers (e.g., Ti and/or TiN, such as a TiN-on-Ti bilayer), and/or covered by conventional adhesion, barrier, hillock suppression, and/or antireflective layers (e.g., Ti, TiN, WN, TiW alloy, or a combination thereof, such as a TiN-on-Ti bilayer or a TiW-on-Ti bilayer.

As shown in FIG. 5, a trench 37 is formed between adjacent metal wires 35. The trench 37 may be formed by forming a first photoresist pattern (not shown) on the uppermost dielectric/insulating layer 30 and then etching the insulating layers exposed by the first photoresist pattern. In an alternative embodiment, the trench 37 may be etched into pre-metal insulating film 20 (e.g., using a timed etch). The trench 37 may be formed in a region of the layer 30 corresponding to the light receiving device 15.

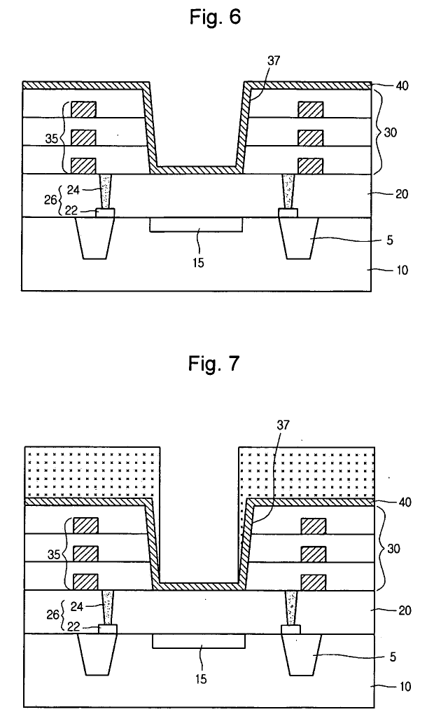

As shown in FIG. 6, a protective film 40 is conformally deposited on the metal wire layer 30 including the trench 37. The protective film 40 may comprise TiN, Ta, TaN, TiSiN, W or Al, and may be formed using a spin coating method or a chemical vapor deposition (CVD) method. The protective film 40 may reduce or prevent light from being incident upon metal wire layer 30.

As shown in FIG. 7, a second photoresist pattern 25 is formed on the protective film 40. The second photoresist pattern 25 may be formed on all regions except a bottom surface of the trench 37.

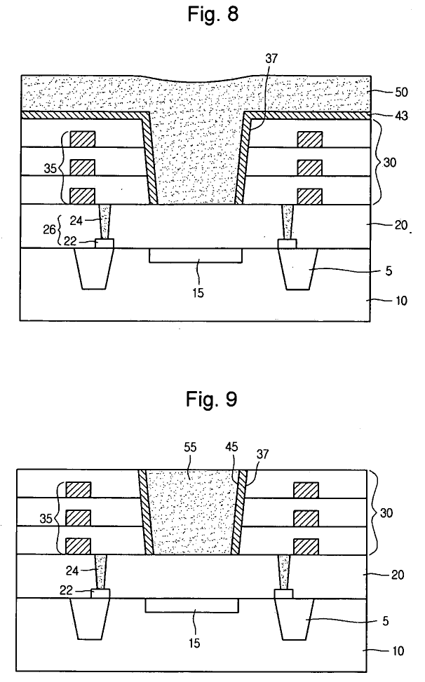

As shown in FIG. 8, an etching process is performed using the second photoresist pattern 25 as a mask to form a first protective pattern 43, and then a photosensitive material 50 is formed on the semiconductor substrate 10 so that the trench 37 may be filled.

The portion of protective film 40 formed on the bottom surface of the trench 37 is removed using the etching process, so that the protective film 40 remains only on the sidewalls of the trench 37 and the upper portion of the metal wire layer 30, thereby forming the first protective pattern 43. The etching process for forming the first protective pattern 43 is preferably performed using Ar gas and/or CₓF_{y} gas (ses) (where x is an integer of from 1 to 5, and y is [2x+2] or, when x is at least 2, 2x), and applying a voltage of 10 to 1000 W and a frequency of 13.56 MHz thereto.

In an alternative embodiment, protective film 40 is anisotropically (e.g. dry plasma) etched to leave sidewall structures (e.g., 45 in FIG. 9) on sidewalls of the trench, prior to filling the trench. This process avoids a photolithography step (e.g. formation of photoresist pattern 25). The planarization (e.g. chemical mechanical polishing) or etchback of the photosensitive material 50 (e.g., hydrogen silsesquioxane or methyl silsesquioxane) to form the structure of FIG. 9 can be conducted by monitoring a light reflection from the interface between the horizontal uppermost surface of insulating layer 30 and the overlying photosensitive material 50 being removed, or a timed etchback or polishing process.

By removing the portion of the protective film 40 formed on the bottom surface of the trench 37, it is possible to increase the amount of light incident upon the light receiving device.

A photosensitive material 50 is formed on the trench and the first protective pattern 43 so that the trench 37 is filled. The photosensitive material 50 may comprise hydrogen silsesquioxane (HSQ) and/or methyl silsesquioxane (MSQ), and may be formed using a CVD method or a spin on glass (SOG) method.

As shown in FIG. 9, a planarization process is performed on the semiconductor substrate 10 to remove the portion of the first protective pattern 43 which has been formed on the upper portion of metal wire layer 30, thus forming second protective pattern 45 and photosensitive material pattern 55.

Because second protective film pattern 45 is formed on the sidewalls of trench 37, when light is incident upon metal wire 35, the light does not pass through or reflect onto an adjacent photodiode due to the second protective pattern 45, so cross talk can be reduced or prevented, and making it possible to reduce or prevent the generation of noise from the image sensor.

Although not shown, a color filter array and micro lens(es) may be formed on the photosensitive material 50.

FIG. 9 is a cross-sectional vies of an image sensor according to the embodiment.

As shown in FIG. 9, an image sensor may include a semiconductor substrate 10 including a device isolating film 5 and a light receiving device 15, a pre-metal insulating film 20 on the semiconductor substrate 10 and including a barrier 26, a metal wire layer 30 on the pre-metal insulating film 20, a trench 37 having a second protective pattern 45 on sidewalls thereof, and a photosensitive material pattern 55 formed so that the trench 37 is filled.

The trench may be formed on a region corresponding to the light receiving device 15. The barrier 26, which may be formed of a poly-silicon pattern 22 and a tungsten plug 24, may be formed on the device isolating film 5. The photosensitive material pattern 55 may be formed of Hydrogen Silsesquioxane (HSQ) and/or Methyl Silsesquioxane (MSQ). The second protective film pattern 45 may comprise Ti, TiN, Ta, TaN, TiSiN, W, WN, WSiN, and/or Al.

As described above, the present image sensor and method for manufacturing thereof has the following advantages.

By forming a photosensitive material in a trench with a protective pattern on sidewalls of the metal wire layer, it is possible to improve sensitivity of an image sensor. When light is incident upon a metal wire, the light does not pass through or reflect onto an adjacent photodiode due to a protective film pattern formed on the sidewalls of the trench, so that cross talk can be reduced or prevented, and making it possible to reduce or prevent the generation of noise from or in the image sensor.

A tungsten barrier may be formed on a metal insulating layer formed between a metal wire layer and a semiconductor substrate, so that light is not emitted externally but rather is concentrated on a pixel region, thereby making it possible to improve sensitivity of an image sensor.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An image sensor, comprising:
a semiconductor substrate including a device isolating film and a light receiving device;
an insulating film on the semiconductor substrate;
a barrier;
a metal wire layer on the insulating film;
a trench between adjacent metal wires having a protective film pattern on sidewalls thereof; and
a photosensitive material in the trench.

2. The image sensor according to claim 1, wherein the trench is on or over a region corresponding to the light receiving device.

3. The image sensor according to claim 1, wherein the barrier is on or over the device isolating film.

4. The image sensor according to claim 1, wherein the barrier comprises poly-silicon and/or tungsten.

5. The image sensor according to claim 1, wherein the photosensitive material comprises hydrogen silsesquioxane (HSQ) and/or methyl silsesquioxane (MSQ).

6. The image sensor according to claim 1, wherein the trench is in a dielectric layer on the metal wire layer.

7. The image sensor according to claim 1, wherein the trench is in a plurality of dielectric layers on a respective plurality of metal wire layers.

8. The image sensor according to claim 1, wherein the protective film pattern comprises TiN, Ta, TaN, TiSiN, W, WN, WiSiN, or Al.

9. The image sensor according to claim 1, wherein the semiconductor substrate comprises a low-concentration p type epitaxial layer on a high-concentration p++ type silicon substrate.

10. A method for manufacturing an image sensor, comprising the steps of:
forming an insulating film on a semiconductor substrate, the semiconductor substrate having a device isolating film, a barrier and a light receiving device;
forming a metal wire layer on the insulating film;
forming a trench between adjacent metal wires;
forming a protective film pattern on surfaces of the trench;
forming a photosensitive material over the metal wire layer and in the trench; and
planarizing the semiconductor substrate to remove portions of the photosensitive material over the metal wire layer.

11. The method according to claim 10, wherein the trench is in a region corresponding to the light receiving device.

12. The method according to claim 10, wherein forming the insulating film on the semiconductor substrate comprises forming one or more vias and/or trenches in the insulating film and filling the vias and/or trenches with tungsten to form a tungsten plug in each of the vias and/or trenches.

13. The method according to claim 10, wherein planarizing the photosensitive material forms a second protective film pattern by removing a portion of the first protective film pattern from an upper portion of the metal wire layer.

14. The method according to claim 10, further comprising forming the trench in a plurality of dielectric layers on a corresponding plurality of metal wire layers.

15. The method according to claim 14, wherein forming the trench comprises forming a first photoresist pattern on or over the plurality of dielectric layers and then etching the exposed dielectric layer(s).

16. The method according to claim 10, wherein forming the protective film pattern comprises spin coating or chemical vapor deposition.

17. The method according to claim 10, wherein forming the protective film pattern comprises etching using Ar gas and/or CₓF_{y} gas.

18. The method according to claim 10, wherein forming the protective film pattern comprises forming a protective film on or over the metal wire layer including surfaces of the trench, then removing the protective film formed on the bottom surface of the trench.

19. The method according to claim 10, wherein planarizing the semiconductor substrate comprises removing at least a portion of the protective film pattern.

20. The method according to claim 10, wherein forming the insulating film comprises forming a poly-silicon pattern on the device isolating film.
